(19) United States
(12) Patent Application Publication
(10) Pub. No.: US 2023/0359081 A1
(43) Pub. Date: Nov. 9, 2023

(54) DIELECTRIC FILTER BASED DISPLAY SYSTEM

(71) Applicant: Meta Platforms Technologies, LLC, Menlo Park, CA (US)

(72) Inventors: Zhang Jia, San Jose, CA (US); Serhan Isikman, Redwood City, CA (US); Yang Zhao, Woodinville, WA (US); Donghee Nam, San Jose, CA (US); Rungrot Kitsomboonloha, Los Gatos, CA (US); Li Zhang, Campbell, CA (US)

(21) Appl. No.: 18/139,268

(22) Filed: Apr. 25, 2023

Related U.S. Application Data
(60) Provisional application No. 63/339,365, filed on May 6, 2022.

(51) Int. Cl. G09G 3/36; G09G 3/00; G09G 3/3208; G02F 1/13357; G02F 1/1343; H10K 59/50; G02F 1/1335; G09G 3/34; G02B 27/01; G02F 1/137

(52) U.S. Cl. CPC G02F 1/133521; G02B 27/0172; G02F 1/133528; G02F 1/133621; G02F 1/134345; G02F 1/137; G09G 3/001; G09G 3/3208; G09G 3/3413; G09G 3/3607; H10K 59/50; G02B 2027/0112; G02B 2027/0178; G02F 2201/52; G09G 2300/0456; G09G 2300/046; G09G 2320/0209

(57) ABSTRACT

A display assembly with dielectric filters is presented herein. The display assembly includes a light source assembly, a dielectric filter array, and a modulation layer. The light source assembly generates laser light in multiple color channels, and each color channel is associated with a different laser emission spectrum. The dielectric filter array includes respective sets of reflective dielectric filters for each color channel. Each set of reflective dielectric filters is matched to the different laser emission spectrum such that reflective dielectric filters in each set transmit light in the different laser emission spectrum and reflect light outside of the different laser emission spectrum. The modulation layer is positioned between a first electrode layer patterned on the dielectric filter array and a second electrode layer. The modulation layer modulates light from the dielectric filter array based on emission instructions applied via the first and second electrode layers to form an image.

### CROSS REFERENCE TO RELATED APPLICATIONS

This application claims a priority and benefit to U.S. Provisional Pat. Application Serial No. 63/339,365, filed May 6, 2022, which is hereby incorporated by reference in its entirety.

### FIELD OF THE INVENTION

The present disclosure relates generally to displays, and more specifically to a dielectric filter based display system.

### BACKGROUND

Typical liquid crystal display (LCD) and some organic light emitting diode (OLED) displays have absorptive color filters to generate colors such as red (R), green (G), and blue (B) color channels. Typically, these color filters are made of organic pigments that absorb some spectrum and emit the rest from 400-700 nm spectral range, such as an LCD with a white light emitting diode (LED) backlight. A key reason organic filters are used is that they are able to be patterned very precisely using photolithography. The organic pigments or dyes are part of a photoresist that reacts to patterned light. Fujifilm color filters are an example widely used in the industry. The transmission spectrum of the organic color filters are overlaid on top of the backlight spectrum. However, organic color filters only transmit light within the specified spectrum and absorbs the rest. This loss at the organic color filter and loss at the liquid crystal (LC) layer (also a type of absorptive filter) are the major sources of power loss in displays.

### SUMMARY

Embodiments of the present disclosure relate to a display assembly with dielectric filters. The display assembly includes a light source assembly, a dielectric filter array, and a modulation layer. The light source assembly is configured to generate laser light in a plurality of color channels, and each of the plurality of color channels is associated with a different laser emission spectrum. The dielectric filter array includes respective sets of reflective dielectric filters for each of the plurality of color channels, and each set of reflective dielectric filters in the dielectric filter array is matched to the different laser emission spectrum such that reflective dielectric filters in each set transmit light in the different laser emission spectrum and reflect light outside of the different laser emission spectrum. The modulation layer is positioned between a first electrode layer that is patterned on the dielectric filter array and a second electrode layer. The modulation layer modulates light from the dielectric filter array based in part on emission instructions applied via the first and second electrode layers to form an image. The display assembly can be part of a head-mounted display (i.e., headset).

Embodiments of the present disclosure are further directed to a display assembly with an organic light emitting diode (OLED) display. The display assembly comprises a plurality of pixels, and each pixel of the plurality of pixels includes a plurality of subpixels configured to emit light in a plurality of color channels. Each sub-pixel of the plurality of sub-pixels includes a white OLED and a reflective dielectric filter for a color channel of the plurality of color channels. The white OLED generates white light that includes the plurality of color channels. The reflective dielectric filter is configured to transmit light from the white OLED that corresponds to the color channel and reflect light from the white OLED that does not correspond to the color channel.

Embodiments of the present disclosure further relate to a method of operating a display assembly with dielectric filters. The method comprises: generating laser light in a plurality of color channels, and each of the plurality of color channels is associated with a different laser emission spectrum; transmitting light in the different laser emission spectrum and reflecting light outside of the different laser emission spectrum via reflective dielectric filters of a set of reflective dielectric filters in a dielectric filter array that is matched to the different laser emission spectrum, the dielectric filter array including respective sets of reflective dielectric filters for each of the plurality of color channels; modulating light from the dielectric filter array via a modulation layer positioned between a first electrode layer that is patterned on the dielectric filter array and a second electrode layer, based in part on emission instructions applied via the first and second electrode layers; and forming an image from the modulated light.

### BRIEF DESCRIPTION OF THE DRAWINGS

FIGS. 1A and 1B are diagrams of head-mounted displays (HMDs) that include near-eye displays (NEDs), in accordance with one or more embodiments.

FIG. 2 is a cross-sectional view of a display assembly, in accordance with one or more embodiments.

FIG. 3 is a cross-sectional view of a display assembly with a dielectric filter array and a modulation layer, in accordance with one or more embodiments.

FIG. 4 is a cross-sectional view of a pixel in the display assembly of FIG. 3, in accordance with one or more embodiments.

FIG. 5 a cross-sectional view of a display assembly with an organic light emitting diode (OLED) display and a dielectric filter array, in accordance with one or more embodiments.

FIG. 6A is an example cross-sectional view of a pixel in the display assembly of FIG. 5, in accordance with one or more embodiments.

FIG. 6B is another example cross-sectional view of a pixel in the display assembly of FIG. 5, in accordance with one or more embodiments.

FIG. 7 is a flowchart illustrating a process of operating a display assembly with dielectric filters, in accordance with one or more embodiments.

FIG. 8 is a block diagram of a system environment that includes a HMD, in accordance with one or more embodiments.

The figures depict various embodiments for purposes of illustration only. One skilled in the art will readily recognize from the following discussion that alternative embodiments of the structures and methods illustrated herein may be employed without departing from the principles described herein.

### DETAILED DESCRIPTION

Embodiments of dielectric filter based display systems are described herein. As noted above, conventional displays often use absorptive color filters which are sources of power loss. In contrast, more efficient displays (e.g., liquid crystal displays (LCDs), organic light emitting diode (OLED) displays, micro OLED displays, etc.) are presented herein that use dielectric filters instead of conventional color filters.

A dielectric filter may be configured to transmit light in one or more passbands, and to reflect light outside of the one or more passbands. A dielectric filter may comprise a plurality of alternating layers of materials with high refractive indexes and materials with low refractive indexes. The high/low index materials (e.g., TiOx, SiNx, SiOx, TaOx based materials), number of layers, and thickness of the high/low index materials can be selected to obtain dielectric filters of particular characteristics. As presented in this disclosure, a reflective dielectric filter may be a dielectric filter that transmits light in a target color channel, and reflects light outside of the target color channel. Likewise, a transmissive dielectric filter may be a dielectric filter that reflects light in the target color channel, and transmits light outside of the target color channel. One advantage of the dielectric filters presented in this disclosure is that the dielectric filters can be matched to particular spectrum of light, which can be narrowband. The number of layers in a matched dielectric filter may range from, e.g., 6-80 layers. Note that, in general, the number of layers decreases as the spectrum of the emission source narrows. Thus, for narrowband emission sources (e.g., lasers), dielectric filters may be made quite thin, i.e., with a relatively small number of layers.

The display assembly presented herein may be integrated into a wearable device (e.g., a head-mounted displays or headset), a mobile device, or any other hardware platform capable of providing artificial reality content to a user.

Embodiments of the present disclosure may include or be implemented in conjunction with an artificial reality system. Artificial reality is a form of reality that has been adjusted in some manner before presentation to a user, which may include, e.g., a virtual reality (VR), an augmented reality (AR), a mixed reality (MR), a hybrid reality, or some combination and/or derivatives thereof. Artificial reality content may include completely generated content or generated content combined with captured (e.g., real-world) content. The artificial reality content may include video, audio, haptic feedback, or some combination thereof, and any of which may be presented in a single channel or in multiple channels (such as stereo video that produces a three-dimensional effect to the viewer). Additionally, in some embodiments, artificial reality may also be associated with applications, products, accessories, services, or some combination thereof, that are used to, e.g., create content in an artificial reality and/or are otherwise used in (e.g., perform activities in) an artificial reality. The artificial reality system that provides the artificial reality content may be implemented on various platforms, including a head-mounted display (or headset) connected to a host computer system, a standalone head-mounted display (or headset), a mobile device or computing system, or any other hardware platform capable of providing artificial reality content to one or more viewers.

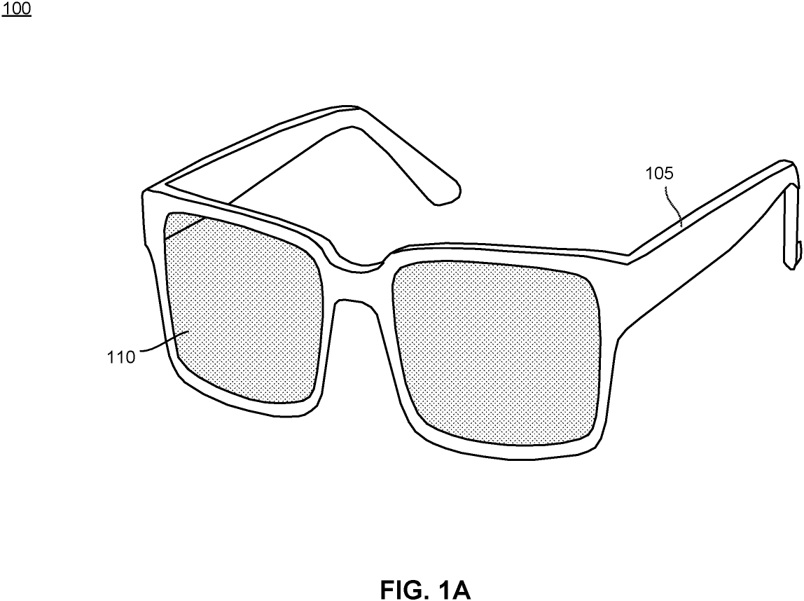

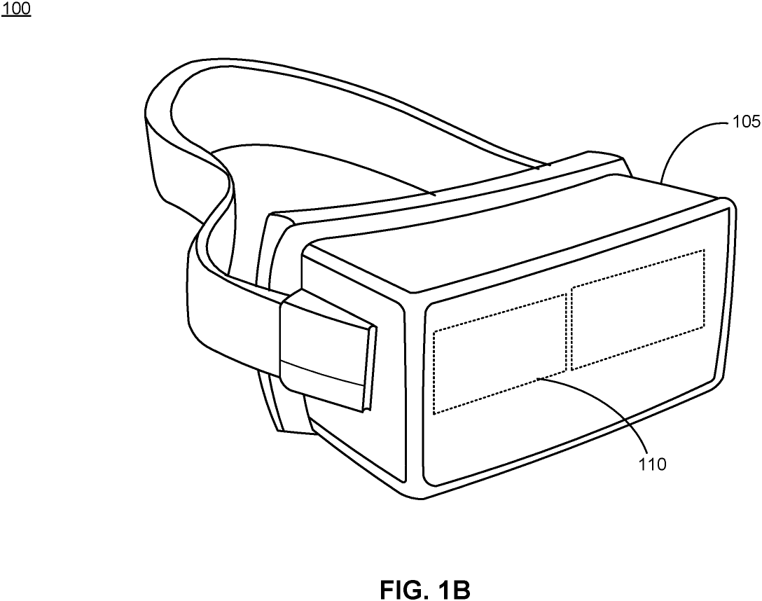

FIGS. 1A and 1B are diagrams of head-mounted displays (HMDs) 100 that include near-eye displays (NEDs), in accordance with one or more embodiments. The NED may present media to a user. Examples of media that may be presented by the NED include one or more images, video, audio, or some combination thereof. In some embodiments, audio may be presented via an external device (e.g., speakers and/or headphones) that receives audio information from the HMD 100, a console (not shown), or both, and presents audio data to the user based on the audio information. The HMD 100 is generally configured to operate as a VR HMD. However, in some embodiments, the HMD 100 may be modified to also operate as an AR HMD, a MR HMD, or some combination thereof. For example, in some embodiments, the HMD 100 may augment views of a physical, real-world environment with computer-generated elements (e.g., still images, video, sound, etc.).

The HMD 100 shown in FIG. 1A or FIG. 1B may include a frame 105 and a display 110. The frame 105 may include one or more optical elements that together display media to a user. That is, the display 110 may be configured for a user to view the content presented by the HMD 100. The display 110 may include at least one light source assembly to generate image light to present optical media to an eye of the user. The light source assembly may include, e.g., a light source, an optics system, or some combination thereof.

FIGS. 1A and 1B are merely examples of a virtual reality system, and the display systems described herein may be incorporated into further such systems.

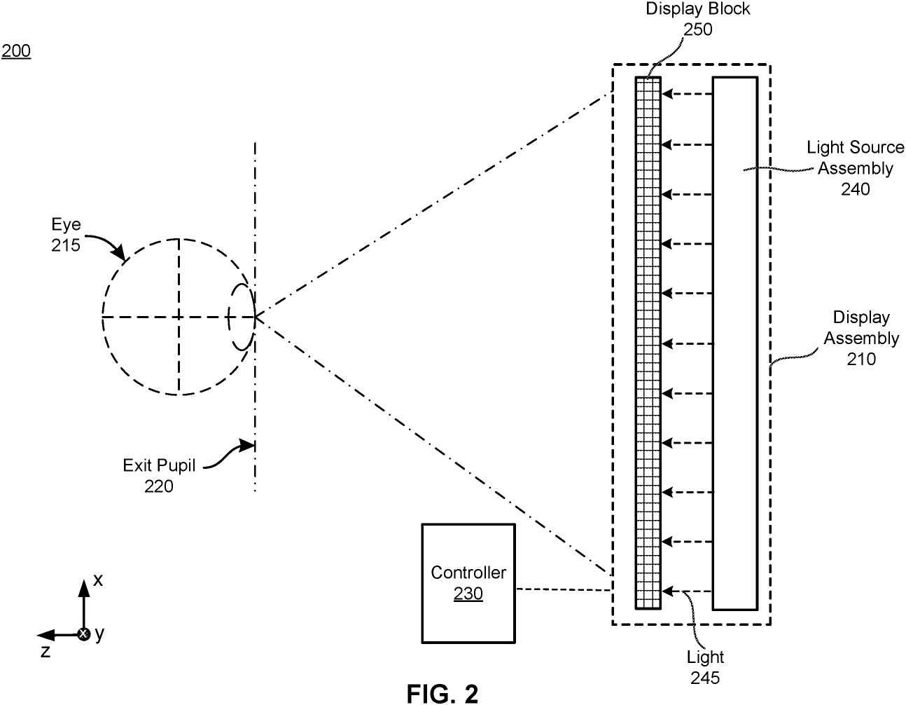

FIG. 2 is a cross-sectional view 200 of a display assembly 210, in accordance with one or more embodiments. In some embodiments, the display 110 may be an embodiment of the display assembly 210. The cross-sectional view 200 shows components of the display assembly 210, an exit pupil 220, as well as a controller 230 coupled to the display assembly 210. The display assembly 210 may include a light source assembly 240 and a display block 250. The exit pupil 220 is a location where an eye 215 may be positioned when a user wears the HMD 100. For purposes of illustration, FIG. 2 shows the cross section 200 associated with a single eye 215 and a single display assembly 210, but in alternative embodiments not shown, another display assembly that is separate from or integrated with the display assembly 210 shown in FIG. 2, may provide image light to another eye of the user.

The display assembly 210 may generate image light and direct the image light to the eye 215 through the exit pupil 220. The display assembly 210 may be composed of one or more materials (e.g., plastic, glass, etc.) with one or more refractive indices that effectively decrease the weight and widen a field of view of the HMD 100. One or more optical elements (not shown in FIG. 2) may be located between the display assembly 210 and the eye 215. The optical elements may act to, by way of various examples, correct aberrations in image light emitted from the display assembly 210, magnify image light emitted from the display assembly 210, perform some other optical adjustment of image light emitted from the display assembly 210, or some combination thereof. Example optical elements may include an aperture, a Fresnel lens, a convex lens, a concave lens, a filter, or any other suitable optical element that may affect image light.

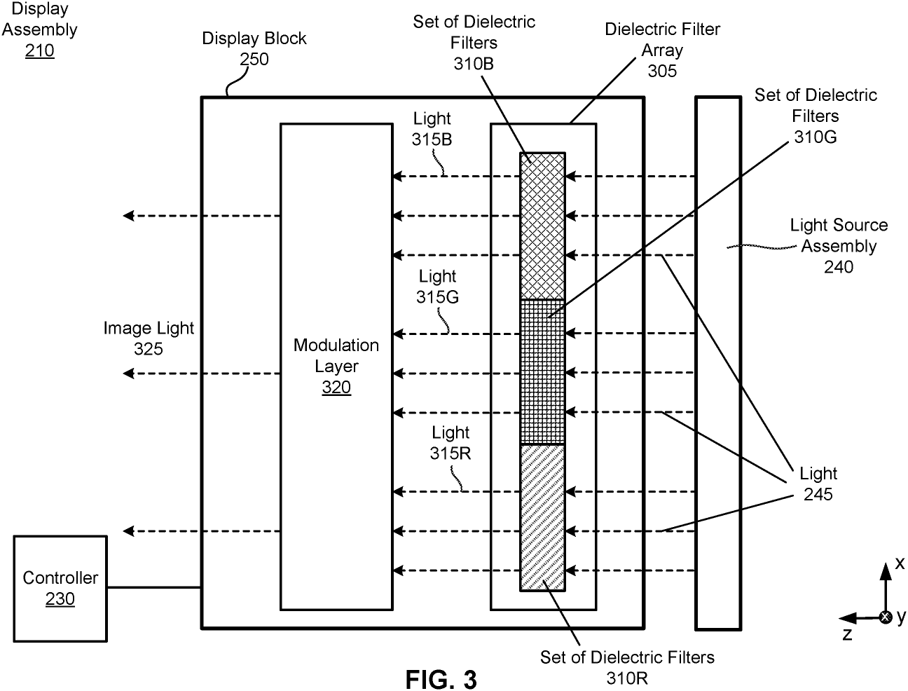

The light source assembly 240 may emit light 245 through the display block 250, e.g., based at least in part on emission instructions from the controller 230. The light source assembly 240 may be configured to generate the light 245 as white light (visible light). The light source assembly 240 may be a backlight device that uses an array of laser emitters as light sources. Alternatively, the light source assembly 240 may be an OLED based display. Details about possible structures and operations of the light source assembly 240 are provided below in relation to FIGS. 3 through 7.

The display block 250 may filter and/or spatially modulate the light 245 received from the light source assembly 240 to generate image light (e.g., an image or content). The display block 250 may include a modulation layer that operates as, e.g., a spatial light modulator. The modulation layer may be a liquid crystal (LC) based (passive or active matrix), or some other type of modulation layer that spatially modulates the light 245 received from the light source assembly 240. In accordance with embodiments of the present disclosure, the display block 250 includes a dielectric filter array for color filtering the light 245 received from the light source assembly 240. And the filtered light may be then transmitted to the modulation layer of the display block 250 that spatially modulates the filtered light to generate the image light. The dielectric filter array may be, e.g., a Bayer pattern, or some other color pattern.

The display block 250 may emit the image light towards the exit pupil 220. In some embodiments, the display block 250 includes an optical element (not shown in FIG. 2) that directs the image light towards the exit pupil 220. The optical element of the display block 250 may magnify the image light, correct optical errors associated with the image light, and present the corrected image light to a user of the HMD 100. The optical element of the display block 250 may direct the magnified and/or corrected image light to the exit pupil 220 for presentation to a user wearing the HMD 100. In various embodiments, the optical element of the display block 250 can be implemented as one or more optical elements. Example optical elements included in the optical element of the display block 250 may include: an aperture, a Fresnel lens, a convex lens, a concave lens, a filter, a reflecting surface, or any other suitable optical element that affects image light. Additional details about a structure and operation of the display block 250 are provided below in relation to FIGS. 3 through 7.

The controller 230 may control components of the display assembly 210. The controller 230 may generate emission instructions for the display assembly 210. The controller 230 may provide the emission instructions to the light source assembly 240. The emission instructions from the controller 230 may include electrical signals (e.g., voltage signals or current signals) that control light emission from the light source assembly 240. For example, the electrical signals having higher amplitude levels (e.g., higher voltage levels or higher current levels) generated by the controller 230 and provided to the light source assembly 240 may prompt the light source assembly 240 to emit the light 245 having a higher brightness level. And, vice versa for the electrical signals generated by the controller 230 having lower amplitude levels. The controller 230 may further control the display block 250 to form the image light from the light 245. Details about controlling the display block 250 to form the image light are provided below in relation to FIGS. 3 through 6B.

### LC Display Systems

FIG. 3 is a cross-sectional view of the display assembly 210 with the display block 250 that includes a dielectric filter array 305 and a modulation layer 320, in accordance with one or more embodiments. As shown in FIG. 3, the display assembly 210 further includes the light source assembly 240 and the controller 230 coupled to the display block 250. The display assembly 210 (and the display block 250) may further include one or more components not shown in FIG. 3, such as a set of crossed linear polarizers, and a secondary color filter array.

The light source assembly 240 may function as a backlight device for the display block 250. The light source assembly 240 may be configured to generate light 245 in a plurality of color channels. The light source assembly 240 may be, e.g., a RGB laser illumination module that emits the light 245 in different color channels, a narrow band source (e.g., UV laser) in combination with a color conversion material that outputs the light 245 in a plurality of color channels (e.g., RGB), a white light source, etc. The light source assembly 240 that operates as a RGB laser illumination module may include a plurality of narrow band sources (e.g., red laser, blue laser, and a green laser).

The dielectric filter array 305 may be configured to separate the light 245 from the light source assembly 240 into individual color channels. The dielectric filter array 305 may include a set of reflective dielectric filters 310R, 310G, 310B for each of the plurality of color channels. Note that in embodiments where the light source assembly 240 is composed of narrowband light sources (e.g., red laser, green laser, blue laser), each set of reflective dielectric filters 310R, 310G, 310B may be matched to a different laser emission spectrum (e.g., red, green or blue emission spectrum) such that reflective dielectric filters in each set of reflective dielectric filters 310R, 310G, 310B transmit light in the different (matched) laser emission spectrum (i.e., target color channel) and reflect light outside of the matched laser emission spectrum. That is, reflective dielectric filters in the set of reflective dielectric filters 310R transmit light 315R in the red (R) emission spectrum and reflect light outside of the red emission spectrum; reflective dielectric filters in the set of reflective dielectric filters 310G transmit light 315G in the green (G) emission spectrum and reflect light outside of the green emission spectrum; and reflective dielectric filters in the set of reflective dielectric filters 310B transmit light 315B in the blue (B) emission spectrum and reflect light outside of the blue emission spectrum. The dielectric filter array 305 may transmit light of individual color channels (i.e., light 315R, light 315G, and light 315B) toward the modulation layer 320.

As the dielectric filter array 305 utilizes sets of reflective dielectric filters 310R, 310G, 310B, a certain amount of light may be reflected back to the light source assembly 240 (e.g., that operates as the backlight device) and may be mixed with light emitted by the light source assembly 240. Because content of image that is presented to a user (i.e., content of image light 325 emitted by the display block 250) determines what portions of light are reflected back to the light source assembly 240, this remix effect may change a color and/or white point of the light 245 (i.e., remixed light). In some embodiments, a color of the image content may be adjusted (e.g., via instructions from the controller 230) while considering the remix effect so that source image/frames may be rendered differently. In some other embodiments, the light source assembly 240 may include an adjustable auxiliary backlight that can compensate the color and/or white point of the remixed light 245. When the light source assembly 240 includes a laser backlight device, a gain of each color channel of the laser backlight device may be adjusted to compensate the color and/or white point of the remixed light 245. Otherwise, the LED-based light source assembly 240 may be designed to include a backlight device with a variable white point (e.g., by populating the backlight device with RGB LEDs or white LEDs with different white points) to dynamically compensate the content-induced white point change.

The modulation layer 320 may be configured to modulate light from the dielectric filter array 305 to generate the image light 325, i.e., an image or content for presentation to a user of the display assembly 210. The modulation layer 320 may perform, e.g., spatial modulation of each individual color channel light 315R, 315G, 315B coming from the dielectric filter array 305 to generate the image light 325 that includes light components of the plurality of color channels (e.g., R, G, B color channels). By performing the spatial modulation, the modulation layer 320 may improve spatial uniformity of the image light 325 in comparison with that of light 315B, 315G, 315R from the dielectric filter array 305.

The modulation layer 320 may include a LC layer and a control circuitry. The control circuitry may include thin-film transistors (TFTs), a first electrode layer, and a second electrode layer (not shown in FIG. 3 for simplicity). Alternatively, instead of TFTs, complementary metal-oxide semiconductor (CMOS) transistors may be employed. The control circuitry may be directly coupled to the controller 230. In one or more embodiments, the control circuitry can be considered a circuitry separate from the modulation layer 320. The LC layer in the modulation layer 320 may modulate the light 315B, 315G, 315R from the dielectric filter array 305 based in part on one or more control signals (e.g., voltage level signals) applied using the first electrode layer and the second electrode layer. The controller 230 may generate the emission instructions including the one or more control signals (e.g., voltage level signals) applied to the modulation layer 320 (e.g., the LC layer) using the first electrode layer and the second electrode layer. The first electrode layer may be patterned on the dielectric filter array 305, and the LC layer may be positioned between the first electrode layer and the second electrode layer. In some embodiments, the TFTs are coupled to the first electrode layer and/or the second electrode layer for providing at least a portion of the one or more control signals (e.g., voltage level signals) to the first electrode layer and/or the second electrode layer. Both the first and second electrode layers may be fully transparent, and made of, e.g., indium tin oxide (ITO) or some other optoelectronic material.

The display block 250 may further include a set of crossed linear polarizers (not shown in FIG. 3 for simplicity). The set of crossed linear polarizers may include, e.g., a first linear polarizer and a second linear polarizer that is orthogonal to the first linear polarizer. The first linear polarizer may polarize light before the light enters the modulation layer 320. For example, the first linear polarizer may be positioned between the light source assembly 240 and the dielectric filter array 305, between the dielectric filter array 305 and the modulation layer 320, or within the modulation layer 320 (e.g., before the LC layer within the modulation layer 320). The second linear polarizer may polarize light that is output from the modulation layer 320 (e.g., from the LC layer within the modulation layer 320). The polarized light transmitted by the second linear polarizer may be the image light 325 that forms an image for the user. The second linear polarizer may be formed on top of the modulation layer 320 (e.g., on top of the LC layer), or on top of an optional secondary color filter array included in the display block 250.

The display block 250 may further include a secondary color filter array positioned in an optical series with the modulation layer (not shown in FIG. 3 for simplicity). The secondary color filter array may (e.g., weakly) diffuse the image light 325 from the modulation layer 320 (and, optionally, the second linear polarizer) in order to, e.g., increase mixing, uniformity, and/or fill factor of the display block 250. The secondary color filter array may include, e.g., a plurality of dielectric filters or some other high transmission percentage color filters. Note that improvements in fill factor may mitigate the screen door effect in artificial reality systems. In some embodiments, a color filter of the secondary color filter array may be larger than its corresponding reflective dielectric filter of the dielectric filter array 305 in order to, e.g., enhance fill factor of the display block 250.

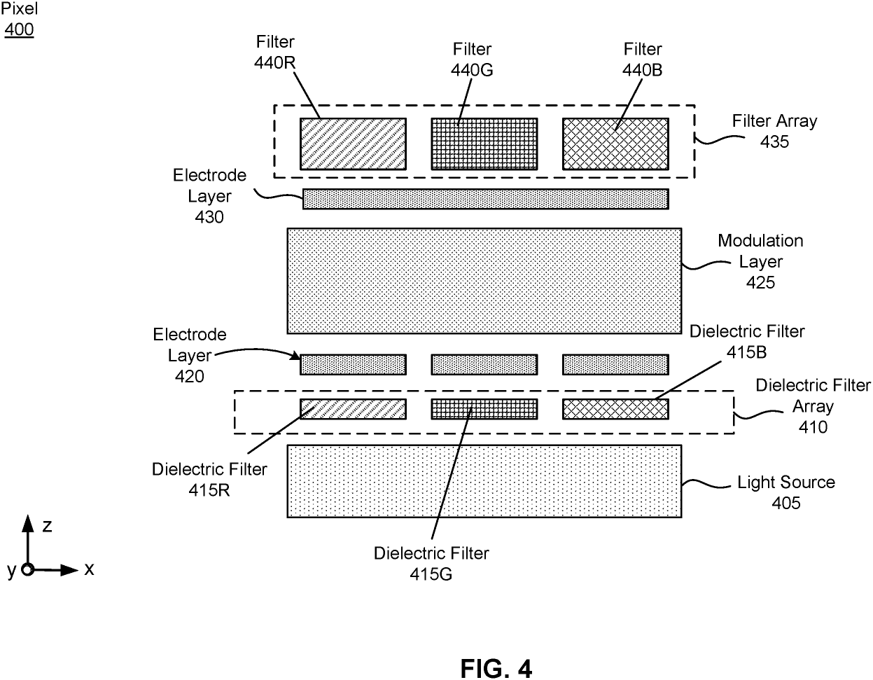

The dielectric filter array 305 and the modulation layer 320 may form a plurality of pixels of the display block 250. Each pixel of the display block 250 may include a plurality of sub-pixels of different color channels (e.g., R, G, B color channels). In some embodiments, there is a single sub-pixel for each color channel in a pixel of the display block 250. But in other embodiments, a single pixel of the display block 250 may include a plurality of sub-pixels in a single color channel in addition to sub-pixels of other color channels (e.g., each pixel includes two green sub-pixels, a single red sub-pixel, and a single blue sub-pixel). In some embodiments, all of the sub-pixels in a given pixel of the display block 250 have an emission area of a same size. But in other embodiments, one or more of the sub-pixels in a given pixel of the display block 250 may have different sized emission areas. Each sub-pixel of the display block 250 may include a portion of a respective set of reflective dielectric filters 310R, 310B, 310G, a respective portion of the modulation layer 320 (including a respective portion of the control circuitry). In some embodiments, one of the electrode layers in the control circuitry (i.e., the first electrode layer or the second electrode layer) may be common to multiple sub-pixels. More details about a structure of a pixel of the LC-based display block 250 of FIG. 3 are provided below in relation to FIG. 4.

Note that in conventional LCDs, a substantial portion of light (e.g., half or ⅔) may be lost at absorptive organic filters. In contrast, the LC-based display block 250 of FIG. 3 includes the dielectric filter array 305 that is formed above the backlight (i.e., above the light source assembly 240) before the modulation layer 320. The dielectric filter array 305 itself transmits desired spectral range and reflects the rest, having little absorption thus light loss. The exact position and layout of the dielectric filter array 305 may be adapted to each display cell design.

The advantage of light recycling through the dielectric filter array 305 may be especially significant with laser illuminated LCDs, e.g., the LC-based display assembly 210 of FIG. 3 with the light source assembly 240 having an array of lasers that generate laser light 245. Laser illuminated LCDs allows a fundamental reduction in in-band chromatic aberrations and a large color gamut. However, lasers also usually have lower efficiency compared to light emitting diode (LED) based emitters. The dielectric filter array 305 may allow improvement in overall light efficiency. With the light source assembly 240 operating as, e.g., an RGB laser illumination module, the wavelengths between the three color channels (e.g., R, G, B color channels) may be completely separated, which allows a simpler design and a simpler fabrication of the dielectric filter array 305. Specifically, the simpler design of the dielectric filter array 305 may result in fewer layers and thinner thickness. This enables easier patterning and smaller pixels (e.g., 5-10 um). Such deposition and patterning of filters in the dielectric filter array 305 may be compatible with silicon process and panel process (e.g., glass substrate). The filters of the dielectric filter array 305 may be patterned above or below transparent electrode layers (e.g., ITO-based layers) next to the TFTs or CMOS transistors of the control circuitry.

FIG. 4 is a cross-sectional view of a pixel 400 in the LC-based display assembly 210 of FIG. 3, in accordance with one or more embodiments. The pixel 400 may emit a portion of image light (e.g., a portion of the image light 325) having a plurality of color channels (e.g., R, G, and B color channels). The pixel 400 may include a light source 405, a dielectric filter array 410, an electrode layer 420, a modulation layer 425, an electrode layer 430, and an optional filter array 435. The pixel 400 may further include one or more components not shown in FIG. 4. For example, the pixel 400 may include a set of crossed linear polarizers that are not shown in FIG. 4 for simplicity.

The light source 405 may generate light (e.g., laser light) in the plurality of color channels. The light source 405 may include one or more laser emitters that generate the multi-color light. The light source 405 may operate as, e.g., a backlight for the pixel 400. The light source 405 may encompass a portion of the light source assembly 240. The multi-color light generated by the light source 405 may be transmitted toward the dielectric filter array 410.

The dielectric filter array 410 may include a respective reflective dielectric filter for each color channel of the plurality of color channels. Thus, as shown in FIG. 4, the dielectric filter array 410 may include a reflective dielectric filter 415R, a reflective dielectric filter 415G, and a reflective dielectric filter 415B. Each of the reflective dielectric filters 415R, 415G, 415B may be matched to a respective light emission spectrum (e.g., red, green, or blue light emission spectrum) such that each reflective dielectric filter 415R, 415G, 415B transmits light in the respective light emission spectrum and reflect light outside of the respective light emission spectrum. The dielectric filter array 410 may be a portion of the dielectric filter array 305, the reflective dielectric filter 415R may be a reflective dielectric filter in the set of dielectric filters 310R, the reflective dielectric filter 415G may be a reflective dielectric filter in the set of dielectric filters 310G, and the reflective dielectric filter 415B may be a reflective dielectric filter in the set of dielectric filters 310B. As the pixel 400 includes a plurality of sub-pixels (e.g., a red sub-pixel, green sub-pixel, and blue sub-pixel), each sub-pixel of the pixel 400 may be associated with a respective reflective dielectric filter 415R, 415G, 415B. The dielectric filter array 410 may transmit light of individual color channels toward the modulation layer 425.

The modulation layer 425 may modulate the light from the dielectric filter array 410 based in part on one or more control signals applied via the electrode layer 420 and the electrode layer 430 to form a portion of an image (e.g., a portion of the image light 325) that corresponds to the pixel 400. The modulation layer 425 may be positioned between the electrode layer 420 and the electrode layer 430. The modulation layer 425 may encompass a portion of the modulation layer 320. Thus, each sub-pixel of the pixel 400 may be associated with a respective portion of the LC layer in the modulation layer 425. In some embodiments (not shown in FIG. 4 for simplicity), wall like structures (e.g., made of one or more isolation materials) may be placed during a fabrication process between adjacent sub-pixels in the pixel 400 and/or between adjacent sub-pixels that belong to different pixels of the LC-based display assembly 210, to mitigate cross-talks between the adjacent sub-pixels.

The electrode layer 420 may be patterned on the dielectric filter array 410. The electrode layer 420 may be coupled to a set of TFTs (not shown in FIG. 4 for simplicity) that provide one or more control signals (e.g., voltage signal levels) from a controller (e.g., the controller 230) to the electrode layer 420. The electrode layer 420 and the set of TFTs may be positioned below the LC layer in the modulation layer 425. In some embodiments, as shown in FIG. 4, the electrode layer 420 may include an array of electrodes, and each electrode of the electrode layer 420 (along with a corresponding subset of TFTs) may be associated with a respective sub-pixel of the plurality of sub-pixels of the pixel 400. Alternatively, the electrode layer 420 (along with the set of TFTs) may be common for all sub-pixels of the pixel 400. Similarly, as shown in FIG. 4, the electrode layer 430 may be common for all sub-pixels of the pixel 400. Alternatively, the electrode layer 430 may be include an array of electrodes, and each electrode of the electrode layer 430 may be associated with a respective sub-pixel of the plurality of sub-pixels of the pixel 400. The electrode layer 430 may be positioned on top of the LC layer in the modulation layer 425. The electrode layers 420, 430 along with the set of TFTs may form a control circuitry that control the modulation of light by the LC layer in the modulation layer 425, which affects intensity of light output for each sub-pixel in the pixel 400.

### OLED Display Systems

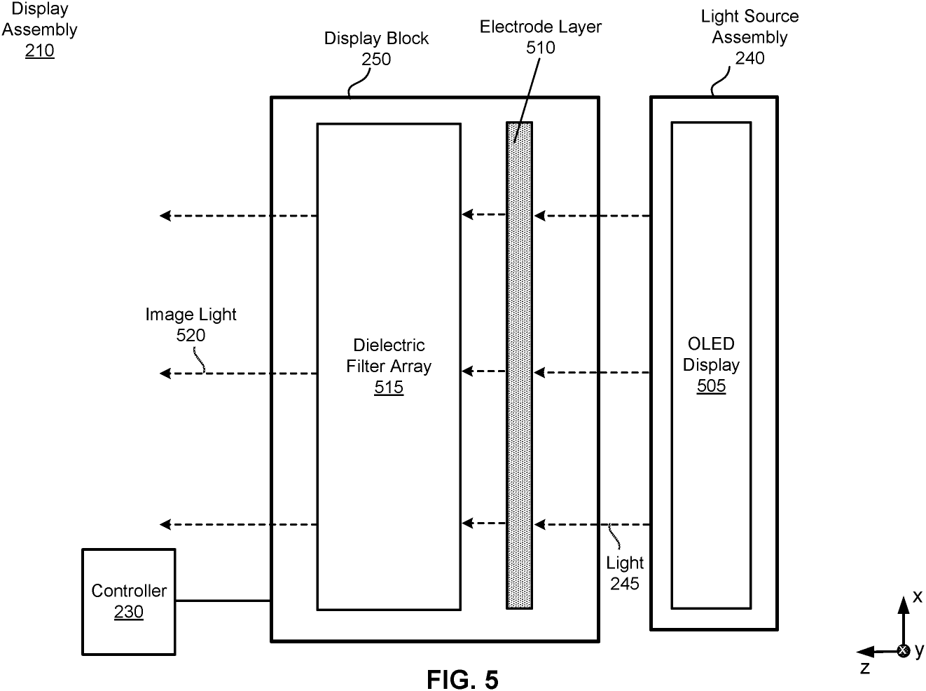

FIG. 5 a cross-sectional view of the display assembly 210 with an OLED display 505 and a dielectric filter array 515, in accordance with one or more embodiments. The light source assembly 240 of the display assembly 210 may include the OLED display 505, and the display block 250 of the display assembly 210 may include an electrode layer 510 and the dielectric filter array 515. The display assembly 210 (and the display block 250) may further include one or more components not shown in FIG. 5, such as a set of crossed linear polarizers, and a secondary dielectric filter array.

The OLED display 505 may emit white light having a plurality of color channels (e.g., R, G, B color channels). The OLED display 505 may include an array of OLEDs (e.g., white OLEDs) that generate the white light. Alternatively, the OLED display 505 may include an array of micro OLEDs (e.g., white micro OLEDs) that generate the white light. The OLED display 505 may encompass a plurality of pixels of the display assembly 210, and each pixel of the plurality of pixels may include a plurality of sub-pixels (e.g., red, green, and blue sub-pixels). The OLED display 505 may transmit the white light toward the dielectric filter array 515.

The OLED display 505 may generate the white light based in part on emission instructions (e.g., generated by the controller 230) applied at least in part via the electrode layer 510. The emission instructions may include one or more control signals generated by the controller 230 and applied at least in part via the electrode layer 510 to control an intensity of the white light emitted by the OLED display 505. The electrode layer 510 may be fully transparent, and made of, e.g., ITO or some other optoelectronic material. The electrode layer 510 may include an electrode that is common for all pixels of the display assembly 210. Alternatively, the electrode layer 510 may be include an array of electrodes, and each electrode of the electrode layer 510 may be associated with a respective sub-pixel of the plurality of sub-pixels.

The dielectric filter array 515 may be configured to separate the white light from the OLED display 505 into image light 520 of individual color channels (e.g., red, green, and blue light), which forms an image. The dielectric filter array 515 may include a set of reflective dielectric filters for each individual color channel. The set of reflective dielectric filters in the dielectric filter array 515 may be matched to a different emission spectrum (e.g., red, green, or blue emission spectrum) such that reflective dielectric filters in the set of reflective dielectric filters transmit light in the different (matched) emission spectrum (i.e., target color channel) and reflect light outside of the matched emission spectrum. The dielectric filter array 515 may encompass the plurality of pixels of the OLED-based display assembly 210, and a subset of reflective dielectric filters in the dielectric filter array 515 that are matched to a plurality of emission spectrums (e.g., red, green, and blue emission spectrums) may be associated with sub-pixels of a single pixel of the OLED-based display assembly 210.

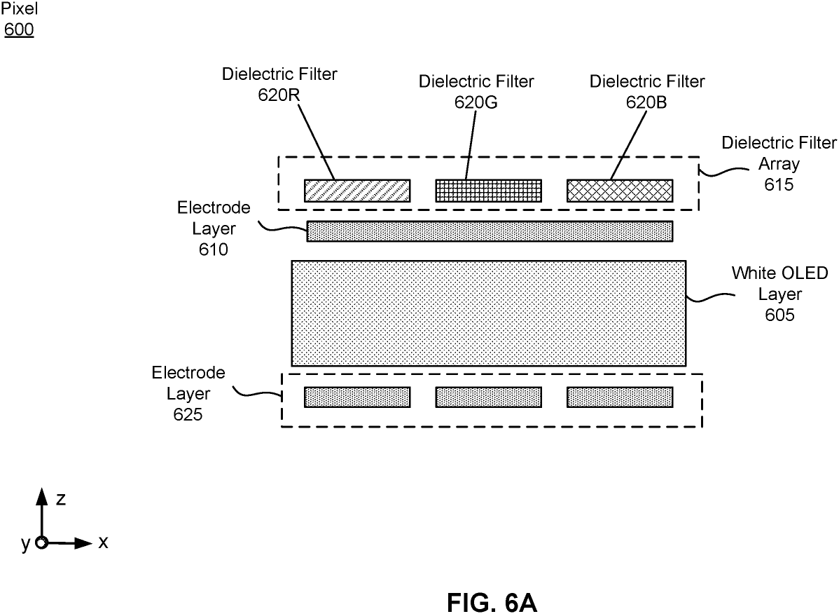

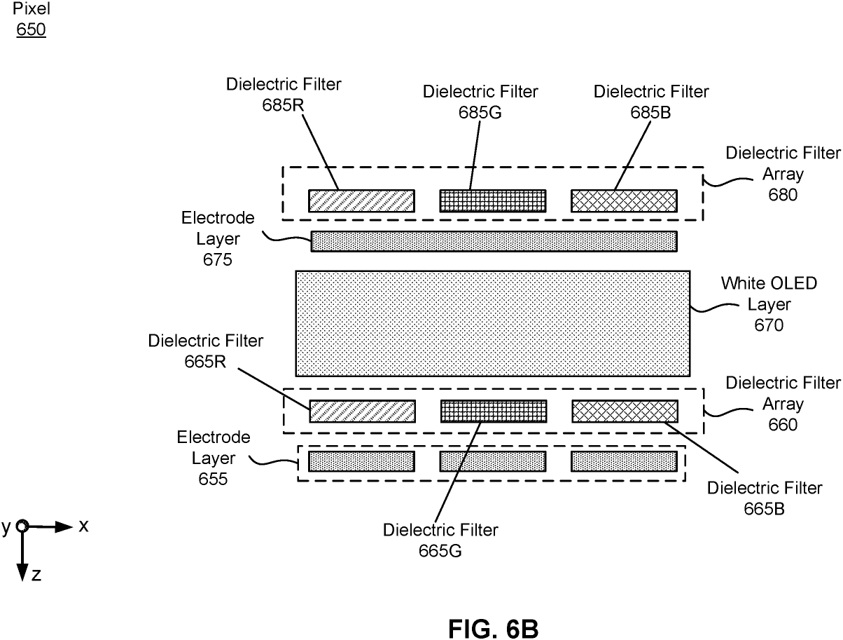

As aforementioned, each pixel of the OLED-based display assembly 210 may include a plurality of sub-pixels of different color channels (e.g., R, G, B color channels). A sub-pixel is configured to emit light of a single color channel. In some embodiments, there is a single sub-pixel for each color channel in a pixel of the OLED-based display assembly 210. But in other embodiments, a single pixel of the OLED-based display assembly 210 includes a plurality of sub-pixels in a single color channel in addition to sub-pixels of other color channels (e.g., each pixel includes two green sub-pixels, a single red sub-pixel, and a single blue sub-pixel). In some embodiments, all of the sub-pixels in a given pixel of the OLED-based display assembly 210 have an emission area of a same size. But in other embodiments, one or more of the sub-pixels may have different sized emission areas. More details about a structure of a pixel of the OLED-based display assembly 210 are provided below in relation to FIGS. 6A-6B.

FIG. 6A is an example cross-sectional view of a pixel 600 in the OLED-based display assembly 210 of FIG. 5, in accordance with one or more embodiments. The pixel 600 may include a white OLED layer 605, an electrode layer 610, a dielectric filter array 615, and an electrode layer 625. The electrode layer 610 and the electrode layer 625 may be part of a control circuitry of the pixel 600. The pixel 600 may include one or more components not shown in FIG. 6A.

The white OLED layer 605 may generate and emit white light toward the dielectric filter array 615. The white OLED layer 605 may include an array of white OLEDs. A portion of the white OLED layer 605 (e.g., one or more respective white OLEDs) may transmit white light for a corresponding sub-pixel of the pixel 600. The white OLED layer 605 may be a portion of the OLED display 505 associated with the single pixel 600. The pixel 600 may be composed of a plurality of sub-pixels (e.g., at least one red sub-pixel, at least one green subpixel, and at least one blue sub-pixel). Each sub-pixel of the pixel 600 may include a corresponding portion of the white OLED layer 605 configured to generate white light that includes a plurality of color channels.

The dielectric filter array 615 may separate the white light from the white OLED layer 605 into different color channels (e.g., R, G, and B color channels). Each sub-pixel of the pixel 600 may include a respective reflective dielectric filter 620R, 620G, 620B of the dielectric filter array 615 for a color channel of the plurality of color channels. The respective reflective dielectric filter 620R, 620G, 620B may be configured to transmit light from a portion of the white OLED layer 605 (e.g., at least one white OLED) that corresponds to the color channel (e.g., R, G, or B color channel) and reflect light from the portion of the white OLED layer 605 that does not correspond to the color channel. In some embodiments, the respective reflective dielectric filter 620R, 620G, 620B may be tuned to closely match a portion of the emission spectrum of the portion of the white OLED layer 605 (e.g., at least one white OLED) that corresponds to the color channel. In some embodiments (not shown in FIG. 6A for simplicity), wall like structures (e.g., made of one or more isolation materials) may be placed during a fabrication process between adjacent sub-pixels in the pixel 600 and/or between adjacent sub-pixels that belong to different pixels of the OLED-based display assembly 210, to mitigate cross-talks between the adjacent sub-pixels. The dielectric filter array 615 may be a portion of the dielectric filter array 515 associated with the single pixel 600.

The control circuitry of the pixel 600 may control which portion of the white OLED layer 605 emits light, i.e., an intensity of light emitted by each sub-pixel of the pixel 600. The control circuitry of the pixel 600 may include the electrode layer 610, the electrode layer 625, and a set of TFTs (or set of CMOS transistors) coupled to electrode layer 610 and/or the electrode layer 625 (not shown in FIG. 6A for simplicity). The electrode layer 610 may be patterned on the white OLED layer 605. A single electrode of the electrode layer 610 (along with the set of TFTs) may be common for all sub-pixels of the pixel 600. Alternatively, the electrode layer 610 may include an array of electrodes, and each electrode of the electrode layer 610 (along with a corresponding subset of TFTs) may be associated with a respective sub-pixel of the plurality of sub-pixels of the pixel 600. Similarly, as shown in FIG. 6A, the electrode layer 625 may include an array of electrodes, and each electrode of the electrode layer 625 (along with a corresponding subset of TFTs) may be associated with a respective sub-pixel of the plurality of sub-pixels of the pixel 600. Alternatively, the electrode layer 625 (along with the set of TFTs) may be common for all sub-pixels of the pixel 600. The emission instructions (e.g., control signals) may be applied for each sub-pixel of the pixel 600 via the electrode layer 610 and/or the electrode layer 625 to control an intensity of the white light emitted by the corresponding white OLED. The electrode layer 610 may be a portion of the electrode layer 510 associated with the single pixel 600.

FIG. 6B is an example cross-sectional view of a pixel 650 in the OLED-based display assembly 210 of FIG. 5, in accordance with one or more embodiments. The pixel 650 may include an electrode layer 655, a dielectric filter array 660, a white OLED layer 670, an electrode layer 675, and a dielectric filter array 680. The electrode layer 655 and the electrode layer 675 may be part of a control circuitry of the pixel 650. The pixel 650 may include one or more components not shown in FIG. 6B.

The white OLED layer 670 may generate white light that is transmitted toward the dielectric filter array 660. The white OLED layer 670 may be positioned between the (transmissive) dielectric filter array 680 and the (reflective) dielectric filter array 660, thereby forming a cavity within the pixel 650. The white OLED layer 670 may include an array of OLEDs. A portion of the white OLED layer 670 (e.g., one or more respective OLEDs) may transmit white light for a corresponding sub-pixel of the pixel 650. The white OLED layer 670 may be a portion of the OLED display 505 associated with the single pixel 650. The pixel 650 may be composed of a plurality of sub-pixels (e.g., at least one red sub-pixel, at least one green subpixel, and at least one blue sub-pixel). Each sub-pixel of the pixel 650 may include a corresponding portion of the white OLED layer 670 configured to generate white light that includes a plurality of color channels.

The dielectric filter array 660 may separate the white light from the white OLED layer 605 into different color channels (e.g., R, G, and B color channels). Each sub-pixel of the pixel 650 may further include a respective reflective dielectric filter 665R, 665G, 665B of the dielectric filter array 660 for a color channel of the plurality of color channels. The respective reflective dielectric filter 665R, 665G, 665B may be configured to transmit light from the portion of the white OLED layer 670 that corresponds to the color channel (e.g., R, G, or B color channel) and reflect light from the portion of the white OLED layer 670 that does not correspond to the color channel. In some embodiments, the respective reflective dielectric filter 665R, 665G, 665B may be tuned to closely match a portion of the emission spectrum of the portion of the white OLED layer 670 that corresponds to the color channel. In some embodiments (not shown in FIG. 6B for simplicity), wall like structures (e.g., made of one or more isolation materials) may be placed during a fabrication process between adjacent sub-pixels in the pixel 650 and/or between adjacent sub-pixels that belong to different pixels of the OLED-based display assembly 210, to mitigate cross-talks between the adjacent sub-pixels.

The control circuitry of the pixel 650 may control which portion of the white OLED layer 670 emits light, i.e., an intensity of light emitted by each sub-pixel of the pixel 650. The control circuitry of the pixel 650 may include the electrode layer 655, the electrode layer 675, and a set of TFTs (or set of CMOS transistors) coupled to the electrode layer 655 and/or the electrode layer 675 (not shown in FIG. 6B for simplicity). The electrode layer 675 may be patterned on the white OLED layer 605. A single electrode of the electrode layer 675 (along with the set of TFTs) may be common for all sub-pixels of the pixel 650. Alternatively, the electrode layer 675 may include an array of electrodes, and each electrode of the electrode layer 675 (along with a corresponding subset of TFTs) may be associated with a respective sub-pixel of the plurality of sub-pixels of the pixel 650. Similarly, as shown in FIG. 6B, the electrode layer 655 may include an array of electrodes, and each electrode of the electrode layer 655 (along with a corresponding subset of TFTs) may be associated with a respective sub-pixel of the plurality of sub-pixels of the pixel 650. Alternatively, the electrode layer 655 (along with the set of TFTs) may be common for all sub-pixels of the pixel 650. The emission instructions (e.g., control signals) may be applied for each sub-pixel of the pixel 650 via the electrode layer 655 and/or the electrode layer 675 to control an intensity of the white light emitted by the corresponding portion of the white OLED layer 670.

The dielectric filter array 680 may reflect light from the white OLED layer 670. The dielectric filter array 680 may include an array of transmissive dielectric filters 685R, 685G, 685B. Each transmissive dielectric filter 685R, 685G, 685B may reflect light from the white OLED layer 670 that corresponds to a respective color channel (e.g., R, G, or B color channel) towards a corresponding reflective dielectric filter 665R, 665G, 665B of the dielectric filter array 680. In some embodiments, each transmissive dielectric filter 685R, 685G, 685B may be tuned to match a passband of the corresponding reflective dielectric filter 665R, 665G, 665B. This helps enhance an amount of light in the color channel of the corresponding reflective dielectric filter 665R, 665G, 665B that is ultimately output from a corresponding sub-pixel of the pixel 650.

### Implementation Details

The display assemblies described herein may be fabricated using typical wafer processing and deposition techniques (e.g., sputtering and ion assisted sputtering). Moreover, there may be an advantage of having a common electrode (e.g., the common electrode layer 430, the common electrode layer 610, and/or the common electrode layer 675) on a bottom of a filter array (e.g., the filter array 435, the dielectric filter array 615, and/or the dielectric filter array 680) for a simpler fabrication process. Patterning color filters on a blank electrode/glass is easier than pattering on complex TFT features. Note that, in traditional LCDs, a color filter glass (color filters with common electrodes) is typically on the top and a TFT glass is on the bottom, which makes a fabrication process more complex.

Design of the display assemblies presented herein can be relatively simple, particularly, for narrowband light sources (e.g., laser backlights). Moreover, by matching a set of dielectric filters (e.g., set of dielectric filters 310B, 310G, 310R) to specific emission spectrums that have little spectral overlap can greatly improve efficiency relative to conventional broad band sources. For example, one set of dielectric filters may just transmit a single wavelength and reflect the other two wavelengths corresponding to different color channels. Thus, the design of the dielectric filters is relatively easy with a few number of layers. For the display assemblies described herein, the dielectric filters may be patterned to pixel size sequentially, one color channel at a time.

### Example Process

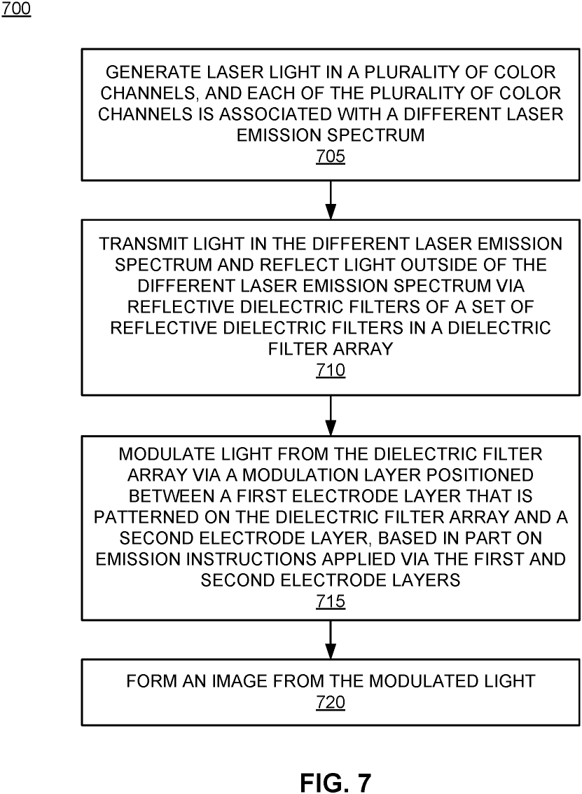

FIG. 7 is a flowchart illustrating a process 700 of operating a display assembly with dielectric filters, in accordance with one or more embodiments. Steps of the process 700 may be performed by one or more components of the display assembly (e.g., the display assembly 210). The display assembly may be capable of being part of a head-mounted display or some other wearable electronic device. Embodiments may include different and/or additional steps of the process 700, or perform the steps of the process 700 in different orders.

The display assembly generates 705 (e.g., via a light source assembly) laser light in a plurality of color channels, and each of the plurality of color channels is associated with a different laser emission spectrum.

The display assembly transmits 710 light in the different laser emission spectrum and reflects light outside of the different laser emission spectrum via reflective dielectric filters of a set of reflective dielectric filters in a dielectric filter array. The set of reflective dielectric filters may be matched to the different laser emission spectrum, and the dielectric filter array may include respective sets of reflective dielectric filters for each of the plurality of color channels. A reflective dielectric filter of the dielectric filter array may comprise at least one first layer of a first refractive index and at least one second layer of a second refractive index that is less than the first refractive index.

The display assembly modulates 715 light from the dielectric filter array via a modulation layer positioned between a first electrode layer that is patterned on the dielectric filter array and a second electrode layer, based in part on emission instructions applied via the first and second electrode layers. The modulation layer may include a LC layer that modulates the light from the dielectric filter array based in part on one or more voltages applied using the first electrode layer and the second electrode layer. The display assembly may polarize light before the light enters the modulation layer using a first linear polarizer. The first linear polarizer may be positioned between the light source assembly and the dielectric filter array, between the modulation layer and the dielectric filter array, or within the modulation layer.

The dielectric filter array and the modulation layer may form a plurality of pixels of the display assembly. Each pixel of the plurality of pixels may include a plurality of sub-pixels associated with the plurality of color channels. Each sub-pixel of the plurality of sub-pixels may include a portion of the modulation layer and a reflective dielectric filter from a respective set of reflective dielectric filters.

The display assembly may further include a second dielectric filter array including second respective sets of dielectric filters for each of the plurality of color channels. Each second set of dielectric filters in the second dielectric filter array may be matched to the different laser emission spectrum such that second dielectric filters in each second set transmits the modulated light in the different laser emission spectrum. The display assembly may further include a plurality of TFTs coupled to at least one of the first electrode layer and the second electrode layer. The TFTs may provide at least a portion of the emission instructions to the at least one of the first electrode layer and the second electrode layer.

The display assembly forms 720 an image from the modulated light. The display assembly may polarize the modulated light that is output from the modulation layer using a second linear polarizer orthogonal to the first linear polarizer to form the image. The second linear polarizer may be formed on top of the modulation layer or on top of a second dielectric filter array included in the display assembly.

### System Environment

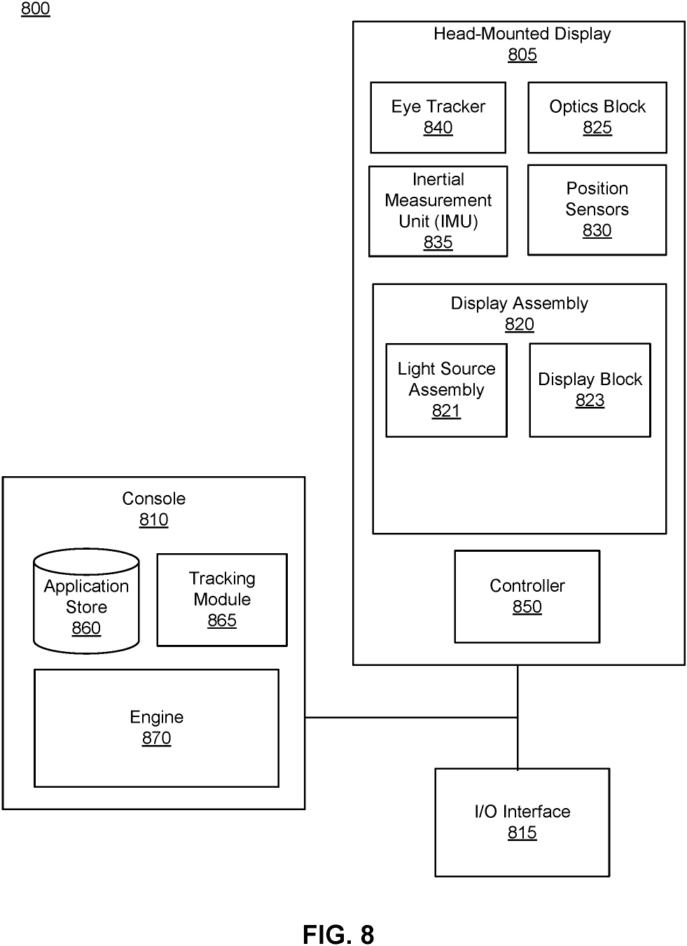

FIG. 8 is a block diagram of a system environment that includes a HMD, in accordance with one or more embodiments. The system 800 may operate in an artificial reality environment, e.g., a virtual reality, an augmented reality, a mixed reality environment, or some combination thereof. The system 800 shown by FIG. 8 comprises a HMD 805 and an input/output (I/O) interface 815 that is coupled to a console 810. While FIG. 8 shows an example system 800 including one HMD 805 and on I/O interface 815, in other embodiments any number of these components may be included in the system 800. For example, there may be multiple HMDs 805 each having an associated I/O interface 815, with each HMD 805 and I/O interface 815 communicating with the console 810. In alternative configurations, different and/or additional components may be included in the system 800. Additionally, functionality described in conjunction with one or more of the components shown in FIG. 8 may be distributed among the components in a different manner than described in conjunction with FIG. 8 in some embodiments. For example, some or all of the functionality of the console 810 is provided by the HMD 805.

The HMD 805 presents content to a user comprising virtual and/or augmented views of a physical, real-world environment with computer-generated elements (e.g., two-dimensional or three-dimensional images, two-dimensional or three-dimensional video, sound, etc.). In some embodiments, the presented content includes audio that is presented via an external device (e.g., speakers and/or headphones) that receives audio information from the HMD 805, the console 810, or both, and presents audio data based on the audio information. The HMD 805 may comprise one or more rigid bodies, which may be rigidly or non-rigidly coupled together. A rigid coupling between rigid bodies causes the coupled rigid bodies to act as a single rigid entity. In contrast, a non-rigid coupling between rigid bodies allows the rigid bodies to move relative to each other. One embodiment of the HMD 805 is the HMD 100 of FIG. 1A. Another embodiment of the HMD 805 is the HMD 100 of FIG. 1B.

The HMD 805 may include a display assembly 820, an optics block 825, one or more position sensors 830, an inertial measurement unit (IMU) 835, an eye tracker 840, and a controller 850. Some embodiments of the HMD 805 have different and/or additional components than those described in conjunction with FIG. 8. Additionally, the functionality provided by various components described in conjunction with FIG. 8 may be differently distributed among the components of the HMD 805 in other embodiments.

The display assembly 820 displays two-dimensional or three-dimensional images to the user in accordance with data received from the console 810. In various embodiments, the display assembly 820 comprises a single display or multiple displays (e.g., a display for each eye of a user). The display assembly 820 may include a light source assembly 821, and a display block 823. An embodiment of the display assembly 820 is the display assembly 210.

The light source assembly 821 may emit light through the display block 823. The light source assembly 821 may function as a backlight for the display assembly 820. The light source assembly 821 may generate light in a plurality of color channels. The light source assembly 821 may be, e.g., an RGB laser illumination module that emits light in different color channels, a narrow band source (e.g., UV laser) in combination with a color conversion material that outputs light in a plurality of color channels (e.g., RGB), a white light source, etc. An RGB laser illumination module may include a plurality of narrow band sources (e.g., red laser, blue laser, and a green laser). An embodiment of the light source assembly 821 is the light source assembly 240.

The display block 823 may filter and spatially modulate the light received from the light source assembly 821 to generate image light for presentation to a user wearing the HMD 805. The display block 250 may include a modulation layer that operates as a spatial light modulator. The modulation layer may be a LC based modulation layer that spatially modulates the light received from the light source assembly 821. Alternatively or additionally, the display block 250 may include a dielectric filter array for filtering the light received from the light source assembly 240. An embodiment of the display block 823 is the display block 250.

The optics block 825 magnifies the image light received from the display assembly 820, corrects optical errors associated with the image light, and presents the corrected image light to a user of the HMD 805. In various embodiments, the optics block 825 includes one or more optical elements. Example optical elements included in the optics block 825 include: an aperture, a Fresnel lens, a convex lens, a concave lens, a filter, a reflecting surface, or any other suitable optical element that affects image light. Moreover, the optics block 825 may include combinations of different optical elements. In some embodiments, one or more of the optical elements in the optics block 825 may have one or more coatings, such as partially reflective or anti-reflective coatings.

Magnification and focusing of the image light by the optics block 825 allows the display assembly 820 to be physically smaller, weigh less, and consume less power than larger displays. Additionally, magnification may increase the field of view of the content presented by the display assembly 820. For example, the field of view of the displayed content is such that the displayed content is presented using almost all (e.g., approximately 110 degrees diagonal), and in some cases all, of the user’s field of view. Additionally, in some embodiments, the amount of magnification may be adjusted by adding or removing optical elements.

In some embodiments, the optics block 825 may be designed to correct one or more types of optical error. Examples of optical error include barrel or pincushion distortion, longitudinal chromatic aberrations, or transverse chromatic aberrations. Other types of optical errors may further include spherical aberrations, chromatic aberrations, or errors due to the lens field curvature, astigmatisms, or any other type of optical error. In some embodiments, content provided to the electronic display for display is pre-distorted, and the optics block 825 corrects the distortion when it receives image light from the electronic display generated based on the content.

The IMU 835 is an electronic device that generates data indicating a position of the HMD 805 based on measurement signals received from one or more of the position sensors 830. A position sensor 830 generates one or more measurement signals in response to motion of the HMD 805. Examples of position sensors 830 include: one or more accelerometers, one or more gyroscopes, one or more magnetometers, another suitable type of sensor that detects motion, a type of sensor used for error correction of the IMU 835, or some combination thereof. The position sensors 830 may be located external to the IMU 835, internal to the IMU 835, or some combination thereof. An embodiment of the position sensor 830 is the position sensor 130.

The eye tracker 840 may track a position of an eye of a user wearing the HMD 805. In one or more embodiments, the eye tracker 840 captures images of the user’s eye, and provides the captured images to the controller 850 for determining a gaze position for the user’s eye. In one or more other embodiments, an internal controller of the eye tracker 840 determines the gaze position for the user’s eye. Information about the gaze position may include information about a position of a pupil of the user’s eye.

The controller 850 may control components of the display assembly 820 and the eye tracker 840. The controller 850 may generate tracking instructions for the eye tracker 840. In some embodiments, the controller 850 receives one or more images of the user’s eye 215 captured by the eye tracker 840 and determines eye tracking information (i.e., gaze information or gaze position) using the captured images. The controller 850 may further generate emission instructions for the display assembly 820 based at least in part on the gaze information. The controller 850 may provide the emission instructions to the light source assembly 821 and/or the display block 823. The emission instructions from the controller 850 may include electrical signals (e.g., voltage signals or current signals) that control light emission from the light source assembly 821 and/or operation of the display block 823. An embodiment of the controller 850 is the controller 230.

The I/O interface 815 is a device that allows a user to send action requests and receive responses from the console 810. An action request is a request to perform a particular action. For example, an action request may be an instruction to start or end capture of image or video data or an instruction to perform a particular action within an application. The I/O interface 815 may include one or more input devices. Example input devices include: a keyboard, a mouse, a game controller, or any other suitable device for receiving action requests and communicating the action requests to the console 810. An action request received by the I/O interface 815 is communicated to the console 810, which performs an action corresponding to the action request. In some embodiments, the I/O interface 815 includes an IMU 835 that captures calibration data indicating an estimated position of the I/O interface 815 relative to an initial position of the I/O interface 815. In some embodiments, the I/O interface 815 may provide haptic feedback to the user in accordance with instructions received from the console 810. For example, haptic feedback is provided when an action request is received, or the console 810 communicates instructions to the I/O interface 815 causing the I/O interface 815 to generate haptic feedback when the console 810 performs an action.

The console 810 provides content to the HMD 805 for processing in accordance with information received from one or more of: the eye tracker 840, the controller 850, and the I/O interface 815. In the example shown in FIG. 8, the console 810 includes an application store 860, a tracking module 865, and an engine 870. Some embodiments of the console 810 have different modules or components than those described in conjunction with FIG. 8. Similarly, the functions further described below may be distributed among components of the console 810 in a different manner than described in conjunction with FIG. 8.

The application store 860 stores one or more applications for execution by the console 810. An application is a group of instructions, that when executed by a processor, generates content for presentation to the user. Content generated by an application may be in response to inputs received from the user via movement of the HMD 805 or the I/O interface 815. Examples of applications include: gaming applications, conferencing applications, video playback applications, or other suitable applications.

The tracking module 865 calibrates the system 800 using one or more calibration parameters and may adjust one or more calibration parameters to reduce error in determination of the position of the HMD 805 or of the I/O interface 815. For example, the tracking module 865 communicates a calibration parameter to the eye tracker 840 to adjust the focus of the eye tracker 840 to determine a gaze position of a user’s eye more accurately. Calibration performed by the tracking module 865 also accounts for information received from the IMU 835 in the HMD 805 and/or an IMU included in the I/O interface 815. Additionally, if tracking of the HMD 805 is lost, the tracking module 865 may re-calibrate some or all of the system 800.

The tracking module 865 tracks movements of the HMD 805 or of the I/O interface 815 using information from the one or more position sensors 830, the IMU 835, or some combination thereof. For example, the tracking module 865 determines a position of a reference point of the HMD 805 in a mapping of a local area based on information from the HMD 805. The tracking module 865 may also determine positions of the reference point of the HMD 805 or a reference point of the I/O interface 815 using data indicating a position of the HMD 805 from the IMU 835 or using data indicating a position of the I/O interface 815 from an IMU 835 included in the I/O interface 815, respectively. Additionally, in some embodiments, the tracking module 865 may use portions of data indicating a position or the HMD 805 from the IMU 835 to predict a future location of the HMD 805. The tracking module 865 provides the estimated or predicted future position of the HMD 805 or the I/O interface 815 to the engine 870.

The engine 870 generates a three-dimensional mapping of the area surrounding the HMD 805 (i.e., the “local area”) based on information received from the HMD 805. In some embodiments, the engine 870 determines depth information for the three-dimensional mapping of the local area that is relevant for techniques used in computing depth. The engine 870 may calculate depth information using one or more techniques in computing depth, such as the stereo based techniques, the structured light illumination techniques, and the time-of-flight techniques. In various embodiments, the engine 870 uses the depth information to, e.g., update a model of the local area, and generate content based in part on the updated model.

The engine 870 also executes applications within the system 800 and receives position information, acceleration information, velocity information, predicted future positions, or some combination thereof, of the HMD 805 from the tracking module 865. Based on the received information, the engine 870 determines content to provide to the HMD 805 for presentation to the user. For example, if the received information indicates that the user has looked to the left, the engine 870 generates content for the HMD 805 that mirrors the user’s movement in a virtual environment or in an environment augmenting the local area with additional content. Additionally, the engine 870 performs an action within an application executing on the console 810 in response to an action request received from the I/O interface 815 and provides feedback to the user that the action was performed. The provided feedback may be visual or audible feedback via the HMD 805 or haptic feedback via the I/O interface 815. Additional Configuration Information

The foregoing description of the embodiments has been presented for illustration; it is not intended to be exhaustive or to limit the patent rights to the precise forms disclosed. Persons skilled in the relevant art can appreciate that many modifications and variations are possible considering the above disclosure.

Some portions of this description describe the embodiments in terms of algorithms and symbolic representations of operations on information. These algorithmic descriptions and representations are commonly used by those skilled in the data processing arts to convey the substance of their work effectively to others skilled in the art. These operations, while described functionally, computationally, or logically, are understood to be implemented by computer programs or equivalent electrical circuits, microcode, or the like. Furthermore, it has also proven convenient at times, to refer to these arrangements of operations as modules, without loss of generality. The described operations and their associated modules may be embodied in software, firmware, hardware, or any combinations thereof.

Any of the steps, operations, or processes described herein may be performed or implemented with one or more hardware or software modules, alone or in combination with other devices. In one embodiment, a software module is implemented with a computer program product comprising a computer-readable medium containing computer program code, which can be executed by a computer processor for performing any or all the steps, operations, or processes described.

Embodiments may also relate to an apparatus for performing the operations herein. This apparatus may be specially constructed for the required purposes, and/or it may comprise a general-purpose computing device selectively activated or reconfigured by a computer program stored in the computer. Such a computer program may be stored in a non-transitory, tangible computer readable storage medium, or any type of media suitable for storing electronic instructions, which may be coupled to a computer system bus. Furthermore, any computing systems referred to in the specification may include a single processor or may be architectures employing multiple processor designs for increased computing capability.

Embodiments may also relate to a product that is produced by a computing process described herein. Such a product may comprise information resulting from a computing process, where the information is stored on a non-transitory, tangible computer readable storage medium and may include any embodiment of a computer program product or other data combination described herein.

Finally, the language used in the specification has been principally selected for readability and instructional purposes, and it may not have been selected to delineate or circumscribe the patent rights. It is therefore intended that the scope of the patent rights be limited not by this detailed description, but rather by any claims that issue on an application based hereon. Accordingly, the disclosure of the embodiments is intended to be illustrative, but not limiting, of the scope of the patent rights, which is set forth in the following claims.

What is claimed is:

1. A display assembly comprising:
a light source assembly configured to generate laser light in a plurality of color channels, and each of the plurality of color channels is associated with a different laser emission spectrum;
a dielectric filter array including respective sets of reflective dielectric filters for each of the plurality of color channels, and each set of reflective dielectric filters in the dielectric filter array is matched to the different laser emission spectrum such that reflective dielectric filters in each set transmit light in the different laser emission spectrum and reflect light outside of the different laser emission spectrum; and
a modulation layer positioned between a first electrode layer that is patterned on the dielectric filter array and a second electrode layer, wherein the modulation layer modulates light from the dielectric filter array based in part on emission instructions applied via the first and second electrode layers to form an image.

2. The display assembly of claim 1, wherein:
the dielectric filter array and the modulation layer form a plurality of pixels;
each pixel of the plurality of pixels includes a plurality of sub-pixels associated with the plurality of color channels; and
each sub-pixel of the plurality of sub-pixels includes a portion of the modulation layer and a reflective dielectric filter from a respective set of reflective dielectric filters.

3. The display assembly of claim 1, wherein the modulation layer includes a liquid crystal (LC) layer, and the LC layer modulates the light from the dielectric filter array based in part on one or more voltages applied using the first electrode layer and the second electrode layer.

4. The display assembly of claim 3, further comprising:
a controller configured to generate the emission instructions including the one or more voltages applied using the first electrode layer and the second electrode layer.

5. The display assembly of claim 1, further comprising:
a first linear polarizer configured to polarize light before the light enters the modulation layer; and
a second linear polarizer orthogonal to the first linear polarizer and configured to polarize the modulated light that is output from the modulation layer, and light transmitted by the second linear polarizer forms the image.

6. The display assembly of claim 5, wherein:
the first linear polarizer is positioned between the light source assembly and the dielectric filter array, between the modulation layer and the dielectric filter array, or within the modulation layer; and
the second linear polarizer is formed on top of the modulation layer or on top of a second dielectric filter array included in the display assembly.

7. The display assembly of claim 1, further comprising:
a second dielectric filter array including second respective sets of dielectric filters for each of the plurality of color channels, and each second set of dielectric filters in the second dielectric filter array is matched to the different laser emission spectrum such that second dielectric filters in each second set transmits the modulated light in the different laser emission spectrum.

8. The display assembly of claim 1, further comprising:
a plurality of thin-film transistors (TFTs) coupled to at least one of the first electrode layer and the second electrode layer, the plurality of TFTs configured to provide at least a portion of the emission instructions to the at least one of the first electrode layer and the second electrode layer.

9. The display assembly of claim 1, wherein a reflective dielectric filter of the dielectric filter array comprises at least one first layer of a first refractive index and at least one second layer of a second refractive index that is less than the first refractive index.

10. The display assembly of claim 1, wherein the display assembly is capable of being part of a head-mounted display.

11. A display assembly comprising:
a plurality of pixels, each pixel of the plurality of pixels includes a plurality of subpixels configured to emit light in a plurality of color channels, and each sub-pixel of the plurality of sub-pixels includes:
a white organic light emitting diode (OLED) configured to generate white light that includes the plurality of color channels, and
a reflective dielectric filter for a color channel of the plurality of color channels, the reflective dielectric filter configured to transmit light from the white OLED that corresponds to the color channel and reflect light from the white OLED that does not correspond to the color channel.

12. The display assembly of claim 11, wherein each sub-pixel of the plurality of sub-pixels further comprises a first electrode layer and a second electrode layer, and emission instructions are applied via the first and second electrode layers to control an intensity of the white light emitted by the white OLED.

13. The display assembly of claim 11, wherein at least a subset of the plurality of sub-pixels share a common electrode, and emission instructions are applied via the common electrodes to control an intensity of the white light emitted by the white OLED.

14. The display assembly of claim 11, wherein each sub-pixel of the plurality of sub-pixels further comprises:
a transmissive dielectric filter for the color channel, the transmissive dielectric filter configured to reflect light from the white OLED that corresponds to the color channel towards the reflective dielectric filter.

15. The display assembly of claim 14, wherein the white OLED is positioned between the transmissive dielectric filter and the reflective dielectric filter forming a cavity.

16. The display assembly of claim 14, wherein the transmissive dielectric filter is tuned to match a passband of the reflective dielectric filter.

17. The display assembly of claim 11, further comprising a wall between a pair of adjacent sub-pixels of the plurality of sub-pixels configured to mitigate a cross talk between the pair of adjacent sub-pixels.

18. The display assembly of claim 11, wherein the display assembly is capable of being part of an electronic wearable device.

19. A method comprising:
generating laser light in a plurality of color channels, and each of the plurality of color channels is associated with a different laser emission spectrum;
transmitting light in the different laser emission spectrum and reflecting light outside of the different laser emission spectrum via reflective dielectric filters of a set of reflective dielectric filters in a dielectric filter array that is matched to the different laser emission spectrum, the dielectric filter array including respective sets of reflective dielectric filters for each of the plurality of color channels;
modulating light from the dielectric filter array via a modulation layer positioned between a first electrode layer that is patterned on the dielectric filter array and a second electrode layer, based in part on emission instructions applied via the first and second electrode layers; and
forming an image from the modulated light.

20. The method of claim 19, further comprising:
polarizing light before the light enters the modulation layer using a first linear polarizer; and
polarizing the modulated light that is output from the modulation layer using a second linear polarizer orthogonal to the first linear polarizer to form the image.
